(19) United States
(12) Patent Application Publication
(10) Pub. No.: US 2026/0133387 A1
(43) Pub. Date: May 14, 2026

(54) OPTICAL DEVICE AND METHOD OF MANUFACTURE

(71) Applicant: Taiwan Semiconductor Manufacturing Co., Ltd., Hsinchu (TW)

(72) Inventors: Chia-Han Tsou, Hsinchu (TW); Ming-Fa Chen, Taichung City (TW)

(21) Appl. No.: 19/085,325

(22) Filed: Mar. 20, 2025

Related U.S. Application Data
(60) Provisional application No. 63/720,461, filed on Nov. 14, 2024.

(51) Int. Cl. G02B 6/42; G02B 6/43; H01L 25/16

(52) U.S. Cl. CPC G02B 6/423; G02B 6/4214; G02B 6/4249; G02B 6/43; H10W 90/00

(57) ABSTRACT

Optical devices and methods of manufacture are presented in a first optical package is received, the first optical package including a first positioning opening and a receptacle opening. A receptacle is inserted into the receptacle opening and the first positioning opening in order to access an edge coupler within the first optical package.

### PRIORITY CLAIM AND CROSS-REFERENCE

This application claims the benefit of U.S. Provisional Application No. 63/720,461, filed on Nov. 14, 2024, which application is hereby incorporated herein by reference.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9 illustrate formation of a first optical package, in accordance with some embodiments.

FIGS. 10A-10C illustrate formation of a receptacle opening and positioning openings, in accordance with some embodiments.

FIGS. 11A-11D illustrate a receptacle, in accordance with some embodiments.

FIGS. 12A-12C illustrate placement of the receptacle into the receptacle opening, in accordance with some embodiments.

FIG. 13 illustrates placement of a fiber array unit, in accordance with some embodiments.

FIGS. 14A-14C illustrate other embodiments of the receptacle opening and the positioning openings, in accordance with some embodiments.

FIG. 15 illustrates another embodiment for collimating and directing optical signals, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which a receptacle is placed within an optical package in order to access an edge coupler within the optical package. The embodiments presented, however, are intended to be illustrative and are not intended to limit the ideas presented to the precise embodiments described. Rather, the ideas presented may be incorporated into a wide variety of embodiments, and all such embodiments may be included within the overall scope of the disclosure.

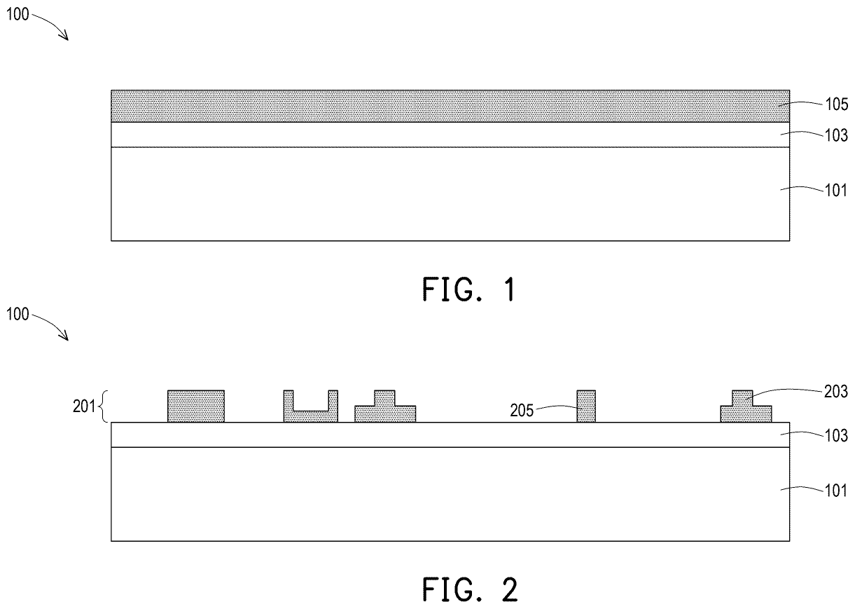

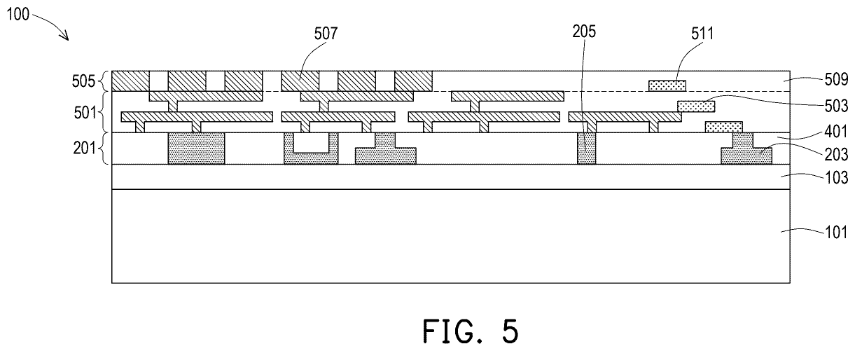

With reference now to FIG. 1, there is illustrated an initial structure of an optical interposer 100 (seen in FIG. 5), in accordance with some embodiments. In the particular embodiment illustrated in FIG. 1, the optical interposer 100 is a photonic integrated circuit (PIC) and comprises at this stage a first substrate 101, a first insulator layer 103, and a layer of material 105 for a first active layer 201 of first optical components 203 (not separately illustrated in FIG. 1 but illustrated and discussed further below with respect to FIG. 2). In an embodiment, at a beginning of the manufacturing process of the optical interposer 100, the first substrate 101, the first insulator layer 103, and the layer of material 105 for the first active layer 201 of first optical components 203 may collectively be part of a silicon-on-insulator (SOI) substrate. Looking first at the first substrate 101, the first substrate 101 may be a semiconductor material such as silicon or germanium, a dielectric material such as glass, or any other suitable material that allows for structural support of overlying devices.

The first insulator layer 103 may be a dielectric layer that separates the first substrate 101 from the overlying first active layer 201 and can additionally, in some embodiments, serve as a portion of cladding material that surrounds the subsequently manufactured first optical components 203 (discussed further below). In an embodiment the first insulator layer 103 may be silicon oxide, silicon nitride, germanium oxide, germanium nitride, combinations of these, or the like, formed using a method such as implantation (e.g., to form a buried oxide (BOX) layer) or else may be deposited onto the first substrate 101 using a deposition method such as chemical vapor deposition, atomic layer deposition, physical vapor deposition, combinations of these, or the like. However, any suitable material and method of manufacture may be used.

The material 105 for the first active layer 201 is initially (prior to patterning) a conformal layer of material that will be used to begin manufacturing the first active layer 201 of the first optical components 203. In an embodiment the material 105 for the first active layer 201 may be a translucent material that can be used as a core material for the desired first optical components 203, such as a semiconductor material such as silicon, germanium, silicon germanium, combinations of these, or the like, while in other embodiments the material 105 for the first active layer 201 may be a dielectric material such as silicon nitride or the like, although in other embodiments the material 105 for the first active layer 201 may be III-V materials, lithium niobate materials, or polymers. In embodiments in which the material 105 of the first active layer 201 is deposited, the material 105 for the first active layer 201 may be deposited using a method such as epitaxial growth, chemical vapor deposition, atomic layer deposition, physical vapor deposition, combinations of these, or the like. In other embodiments in which the first insulator layer 103 is formed using an implantation method, the material 105 of the first active layer 201 may initially be part of the first substrate 101 prior to the implantation process to form the first insulation layer 103. However, any suitable materials and methods of manufacture may be utilized to form the material 105 of the first active layer 201.

FIG. 2 illustrates that, once the material 105 for the first active layer 201 is ready, the first optical components 203 for the first active layer 201 are manufactured using the material 105 for the first active layer 201. In embodiments the first optical components 203 of the first active layer 201 may include such components as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable first optical components 203 may be used.

To begin forming the first active layer 201 of first optical components 203 from the initial material, the material 105 for the first active layer 201 may be patterned into the desired shapes for the first active layer 201 of first optical components 203. In an embodiment the material 105 for the first active layer 201 may be patterned using, e.g., one or more photolithographic masking and etching processes. However, any suitable method of patterning the material 105 for the first active layer 201 may be utilized. For some of the first optical components 203, such as waveguides or edge couplers, the patterning process may be all or at least most of the manufacturing that is used to form these first optical components 203 components.

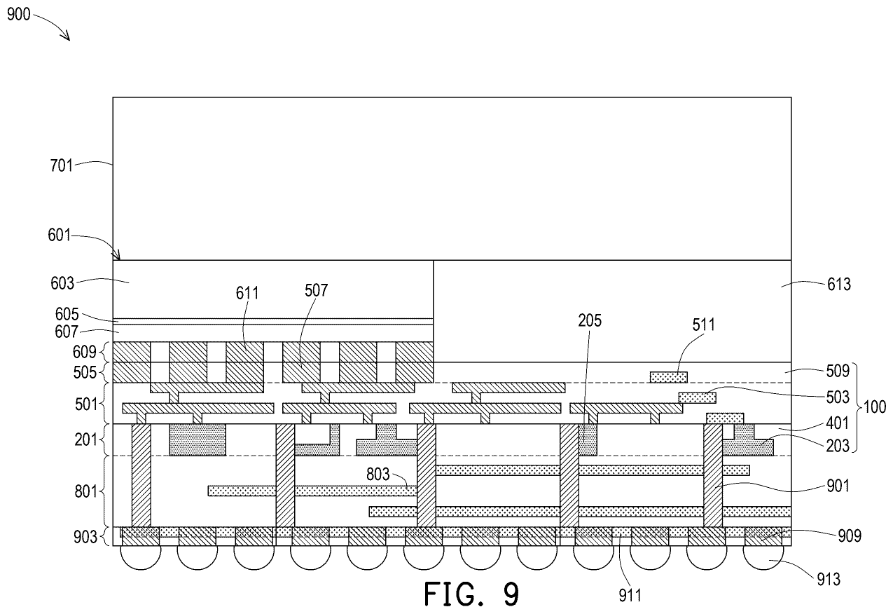

As one of the first optical components 203, there is formed an edge coupler 205 that is not adjacent to an exterior edge of the first optical package 900 (not illustrated in FIG. 2 but illustrated and discussed further below with respect to FIG. 9). The edge coupler 205 is utilized to receive the optical signals 1303 that are in-plane with the edge coupler 205 but from off of the first optical package 900 and direct the optical signals 1303 into an adjacent waveguide and, from there, throughout the remainder of the first optical package 900. However, any suitable structure may be utilized.

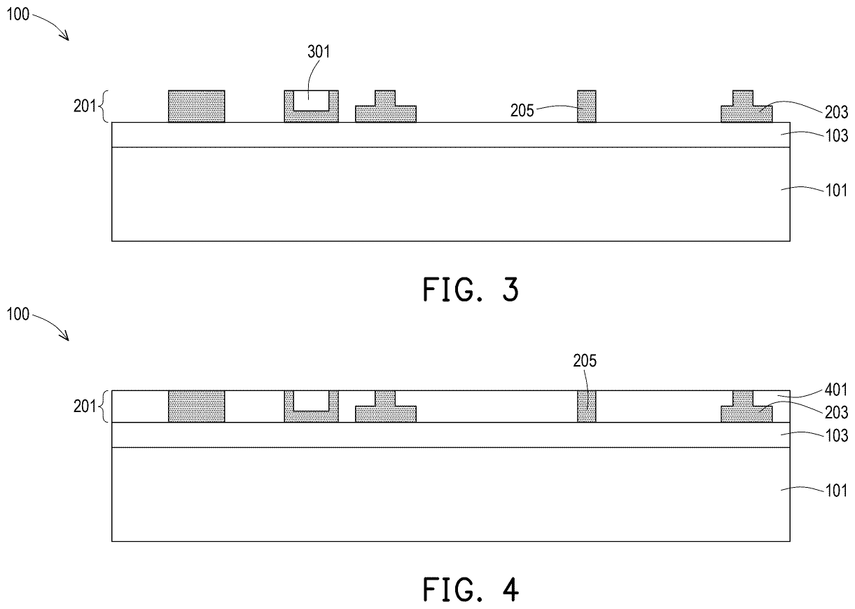

FIG. 3 illustrates that, for those components that utilize further manufacturing processes, such as Mach-Zehnder silicon-photonic switches that utilize resistive heating elements, additional processing may be performed either before or after the patterning of the material for the first active layer 201. For example, implantation processes, additional deposition and patterning processes for different materials (e.g., resistive heating elements, III-V materials for converters), combinations of all of these processes, or the like, can be utilized to help further the manufacturing of the various desired first optical components 203. In a particular embodiment, and as specifically illustrated in FIG. 3, in some embodiments an epitaxial deposition of a semiconductor material 301 such as germanium (used, e.g., for electricity/optics signal modulation and transversion) may be performed on a patterned portion of the material 105 of the first active layer 201. In such an embodiment the semiconductor material 301 may be epitaxially grown in order to help manufacture, e.g., a photodiode for an optical-to-electrical converter. All such manufacturing processes and all suitable first optical components 203 may be manufactured, and all such combinations are fully intended to be included within the scope of the embodiments.

FIG. 4 illustrates that, once the individual first optical components 203 of the first active layer 201 have been formed, a second insulator layer 401 may be deposited to cover the first optical components 203 and provide additional cladding material. In an embodiment the second insulator layer 401 may be a dielectric layer that separates the individual components of the first active layer 201 from each other and from the overlying structures and can additionally serve as another portion of cladding material that surrounds the first optical components 203. In an embodiment the second insulator layer 401 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the second insulator layer 401 has been deposited, the material may be planarized using, e.g., a chemical mechanical polishing process in order to either planarize a top surface of the second insulator layer 401 (in embodiments in which the second insulator layer 401 is intended to fully cover the first optical components 203) or else planarize the second insulator layer 401 with top surfaces of the first optical components 203. However, any suitable material and method of manufacture may be used.

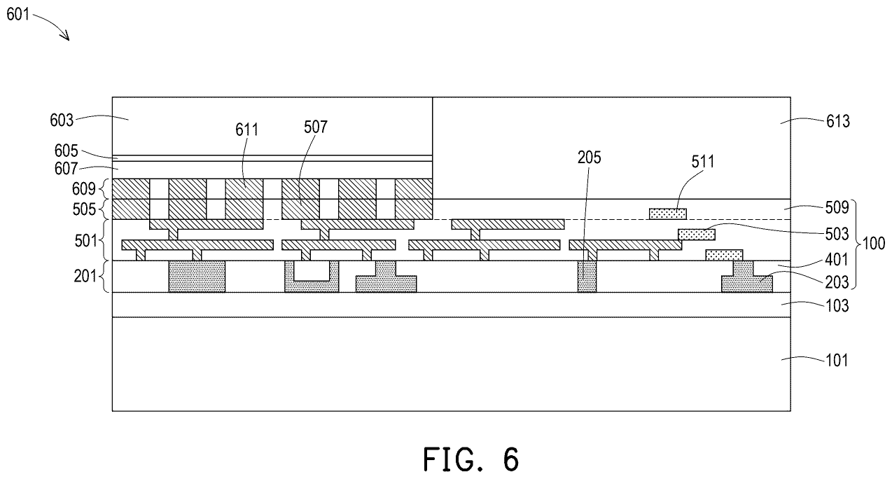

FIG. 5 illustrates that, once the first optical components 203 of the first active layer 201 have been manufactured and the second insulator layer 401 has been formed, first metallization layers 501 are formed in order to electrically connect the first active layer 201 of first optical components 203 to control circuitry, to each other, and to subsequently attached devices (not illustrated in FIG. 5 but illustrated and described further below with respect to FIG. 6). In an embodiment the first metallization layers 501 are formed of alternating layers of dielectric and conductive material and may be formed through any suitable processes (such as deposition, damascene, dual damascene, etc.). In particular embodiments there may be multiple layers of metallization used to interconnect the various first optical components 203, but the precise number of first metallization layers 501 is dependent upon the design of the optical interposer 100.

Additionally, during the manufacture of the first metallization layers 501, one or more second optical components 503 may be formed as part of the first metallization layers 501. In some embodiments the second optical components 503 of the first metallization layers 501 may include such components as couplers (e.g., edge couplers, grating couplers, etc.) for connection to outside signals, optical waveguides (e.g., ridge waveguides, rib waveguides, buried channel waveguides, diffused waveguides, etc.), optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable optical components may be used for the one or more second optical components 503.

In an embodiment the one or more second optical components 503 may be formed by initially depositing a material for the one or more second optical components 503. In an embodiment the material for the one or more second optical components 503 may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, any suitable material and any suitable method of deposition may be utilized.

Once the material for the one or more second optical components 503 has been deposited or otherwise formed, the material may be patterned into the desired shapes for the one or more second optical components 503. In an embodiment the material of the one or more second optical components 503 may be patterned using, e.g., one or more photolithographic masking and etching processes. However, any suitable method of patterning the material for the one or more second optical components 503 may be utilized.

For some of the one or more second optical components 503, such as waveguides or edge couplers, the patterning process may be all or at least most manufacturing that is used to form these components. Additionally, for those components that utilize further manufacturing processes, such as Mach-Zehnder silicon-photonic switches that utilize resistive heating elements, additional processing may be performed either before or after the patterning of the material for the one or more second optical components 503. For example, implantation processes, additional deposition and patterning processes for different materials, combinations of all of these processes, or the like, and can be utilized to help further the manufacturing of the various desired one or more second optical components 503. All such manufacturing processes and all suitable one or more second optical components 503 may be manufactured, and all such combinations are fully intended to be included within the scope of the embodiments.

Once the one or more second optical components 503 of the first metallization layers 501 have been manufactured, a first bonding layer 505 is formed over the first metallization layers 501. In an embodiment, the first bonding layer 505 may be used for a dielectric-to-dielectric and metal-to-metal bond. In accordance with some embodiments, the first bonding layer 505 is formed of a first dielectric material 509 such as silicon oxide, silicon nitride, or the like. The first dielectric material 509 may be deposited using any suitable method, such as CVD, high-density plasma chemical vapor deposition (HDPCVD), PVD, atomic layer deposition (ALD), or the like. However, any suitable materials and deposition processes may be utilized.

Once the first dielectric material 509 has been formed, first openings in the first dielectric material 509 are formed to expose conductive portions of the underlying layers in preparation to form first bond pads 507 within the first bonding layer 505. Once the first openings have been formed within the first dielectric material 509, the first openings may be filled with a seed layer and a plate metal to form the first bond pads 507 within the first dielectric material 509. The seed layer may be blanket deposited over top surfaces of the first dielectric material 509 and the exposed conductive portions of the underlying layers and sidewalls of the openings and the second openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the first dielectric material 509 and sidewalls of the openings and the second openings before the seed layer. The barrier layer may comprise titanium, titanium nitride, tantalum, tantalum nitride, or the like.

Following the filling of the first openings, a planarization process, such as a CMP, is performed to remove excess portions of the seed layer and the plate metal, forming the first bond pads 507 within the first bonding layer 505. In some embodiments a bond pad via (not separately illustrated) may also be utilized to connect the first bond pads 507 with underlying conductive portions and, through the underlying conductive portions, connect the first bond pads 507 with the first metallization layers 501.

Additionally, the first bonding layer 505 may also include one or more third optical components 511 incorporated within the first bonding layer 505. In such an embodiment, prior to the deposition of the first dielectric material 509, the one or more third optical components 511 may be manufactured using similar methods and similar materials as the one or more second optical components 503 (described above), such as by being waveguides and other structures formed at least in part through a deposition and patterning process. However, any suitable structures, materials and any suitable methods of manufacture may be utilized.

FIG. 6 illustrates a bonding of a first semiconductor device 601 to the first bonding layer 505 of the optical interposer 100. In some embodiments, the first semiconductor device 601 is an electronic integrated circuit (EIC - e.g., a device without optical devices) and may have a semiconductor substrate 603, a layer of active devices 605, an overlying interconnect structure 607, a second bonding layer 609, and associated third bond pads 611. In an embodiment the semiconductor substrate 603 may be similar to the first substrate 101 (e.g., a semiconductor material such as silicon or silicon germanium), the active devices 605 may be transistors, capacitors, resistors, and the like formed over the semiconductor substrate 603, the interconnect structure 607 may be similar to the first metallization layers 501 (without optical components), the second bonding layer 609 may be similar to the first bonding layer 505, and the third bond pads 611 may be similar to the first bond pads 507. However, any suitable devices may be utilized.

In an embodiment the first semiconductor device 601 may be configured to work with the optical interposer 100 for a desired functionality. In some embodiments the first semiconductor device 601 may be a logic die, a high bandwidth memory (HBM) module, an xPU, a 3DIC die, a CPU, a GPU, a SoC die, a MEMS die, combinations of these, or the like. Any suitable device with any suitable functionality, may be used, and all such devices are fully intended to be included within the scope of the embodiments.

In an embodiment the first semiconductor device 601 and the first bonding layer 505 may be bonded using a dielectric-to-dielectric and metal-to-metal bonding process. In a particular embodiment which utilizes a dielectric-to-dielectric and metal-to-metal bonding process, the process may be initiated by activating the surfaces of the second bonding layer 609 and the surfaces of the first bonding layer 505. Activating the top surfaces of the first bonding layer 505 and the second bonding layer 609 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the first bonding layer 505 and the second bonding layer 609.

After the activation process the optical interposer 100 and the first semiconductor device 601 may be cleaned using, e.g., a chemical rinse, and then the first semiconductor device 601 is aligned and placed into physical contact with the optical interposer 100. The optical interposer 100 and the first semiconductor device 601 are then subjected to thermal treatment and contact pressure to bond the optical interposer 100. For example, the optical interposer 100 and the first semiconductor device 601 may be subjected to a pressure of about 200 kPa or less, and a temperature between about 25° C. and about 250° C. to fuse the optical interposer 100 and the first semiconductor device 601. The optical interposer 100 and the first semiconductor device 601 may then be subjected to a temperature at or above the eutectic point for material of the first bond pads 507 and the third bond pads 611, e.g., between about 150° C. and about 650° C., to fuse the metal. In this manner, the optical interposer 100 and the first semiconductor device 601 forms a dielectric-to-dielectric and metal-to-metal bonded device. In some embodiments, the bonded dies are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

FIG. 6 additionally illustrates that, once the first semiconductor device 601 has been bonded, a first gap-fill material 613 is deposited in order to fill the space around the first semiconductor device 601 and provide additional support. In an embodiment the first gap-fill material 613 may be a material such as silicon oxide, silicon nitride, silicon oxynitride, combinations of these, or the like, deposited to fill and overfill the spaces around the first semiconductor device 601. However, any suitable material and method of deposition may be utilized.

Once the first gap-fill material 613 has been deposited, the first gap-fill material 613 may be planarized in order to expose the first semiconductor device 601. In an embodiment the planarization process may be a chemical mechanical planarization process, a grinding process, or the like. However, any suitable planarization process may be utilized.

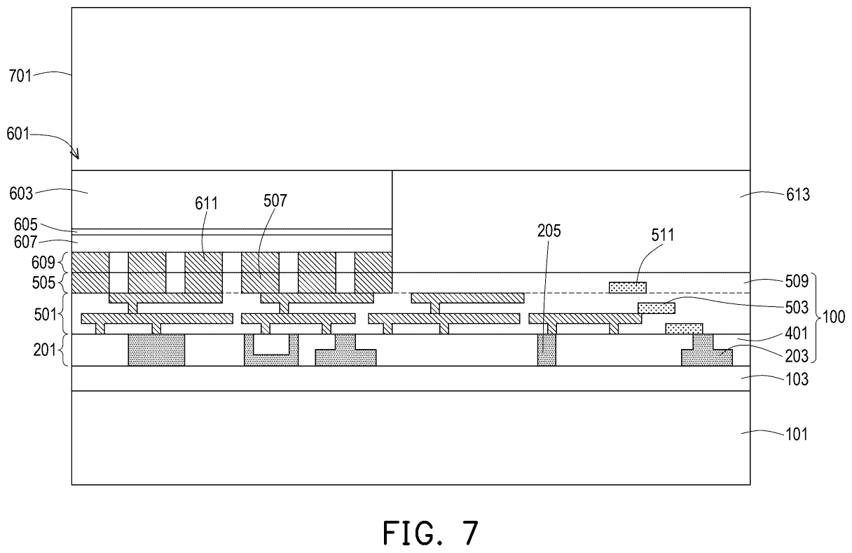

FIG. 7 illustrates an attachment of a support substrate 701 to the first semiconductor device 601 and the first gap-fill material 613. In an embodiment the support substrate 701 may be a support material that is transparent to the wavelength of light that is desired to be used, such as silicon, and may be attached using, e.g., an adhesive (not separately illustrated in FIG. 7). However, in other embodiments the support substrate 701 may be bonded to the first semiconductor device 601 and the first gap-fill material 613 using, e.g., a bonding process. Any suitable method of attaching the support substrate 701 may be used.

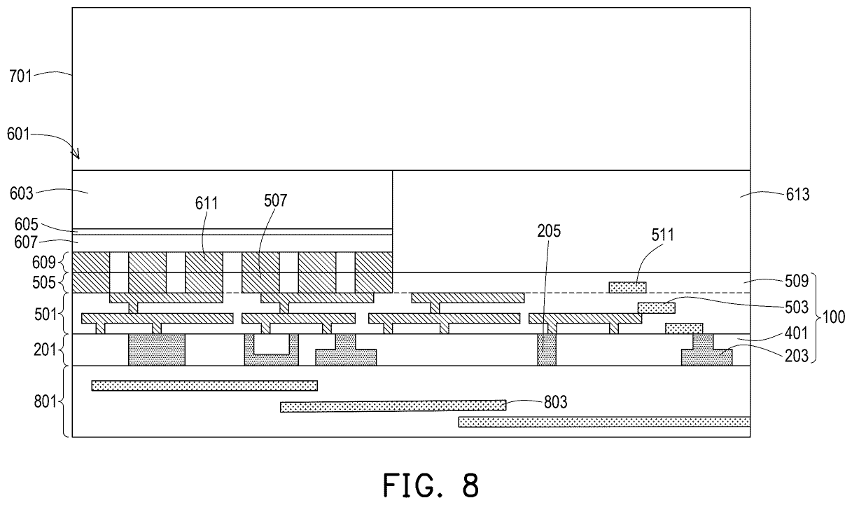

FIG. 8 illustrates a removal of the first substrate 101 and, optionally, the first insulator layer 103, thereby exposing the first active layer 201 of first optical components 203. In an embodiment the first substrate 101 and the first insulator layer 103 may be removed using a planarization process, such as a chemical mechanical polishing process, a grinding process, one or more etching processes, combinations of these, or the like. However, any suitable method may be used in order to remove the first substrate 101 and/or the first insulator layer 103.

Once the first substrate 101 and the first insulator layer 103 have been removed, a second active layer 801 of fourth optical components 803 may be formed on a back side of the first active layer 201. In an embodiment the second active layer 801 of fourth optical components 803 may be formed using similar materials and similar processes as the second optical components 503 of the first metallization layers 501 (described above with respect to FIG. 5). For example, the second active layer 801 of fourth optical components 803 may be formed of alternating layers of a cladding material such as silicon oxide and core material such as silicon nitride formed using deposition and patterning processes in order to form optical components such as waveguides and the like.

FIG. 9 illustrates formation of first through device vias (TDVs) 901 and formation of a third bonding layer 903 to form a first optical package 900 which, in some embodiments is an optical engine. In an embodiment the first through device vias 901 extend through the second active layer 801 and the first active layer 201 so as to provide a quick passage of power, data, and ground through the optical interposer 100. In an embodiment the first through device vias 901 may be formed by initially forming through device via openings into the optical interposer 100. The through device via openings may be formed by applying and developing a suitable photoresist (not shown), and removing portions of the second active layer 801 and the optical interposer 100 that are exposed.

Once the through device via openings have been formed within the optical interposer 100, the through device via openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may also be used.

Once the liner has been formed along the sidewalls and bottom of the through device via openings, a barrier layer (also not independently illustrated) may be formed and the remainder of the through device via openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the through device via openings. Once the through device via openings have been filled, excess liner, barrier layer, seed layer, and first conductive material outside of the through device via openings may be removed through a planarization process such as chemical mechanical polishing (CMP), although any suitable removal process may be used.

Optionally, in some embodiments once the first through device vias 901 have been formed, second metallization layers (not separately illustrated in FIG. 9) may be formed in electrical connection with the first through device vias 901. In an embodiment the second metallization layers may be formed as described above with respect to the first metallization layers 501, such as being alternating layers of dielectric and conductive materials using damascene processes, dual damascene process, or the like. In other embodiments, the second metallization layers may be formed using a plating process to form and shape conductive material, and then cover the conductive material with a dielectric material. However, any suitable structures and methods of manufacture may be utilized.

The third bonding layer 903 is formed in order to provide electrical connections between the optical interposer 100 and subsequently attached devices. In an embodiment the third bonding layer 903 may be similar to the first bonding layer 505, such as having third bond pads 909 (similar to the first bond pads 507) and even fifth optical components 911 (similar to the third optical components 511). However, any suitable devices may be utilized.

FIG. 9 additionally illustrates a placement of first external connectors 913 which may be formed to provide conductive regions for contact between the third bond pads 909 to other external devices. The first external connectors 913 may be conductive bumps (e.g., C4 bumps, ball grid arrays, microbumps, etc.) or conductive pillars utilizing materials such as solder and copper. In an embodiment in which the first external connectors 913 are contact bumps, the first external connectors 913 may comprise a material such as tin, or other suitable materials, such as silver, lead-free tin, or copper. In an embodiment in which the first external connectors 913 are tin solder bumps, the first external connectors 913 may be formed by initially forming a layer of tin through such commonly used methods such as evaporation, electroplating, printing, solder transfer, ball placement, etc. Once a layer of tin has been formed on the structure, a reflow may be performed in order to shape the material into the desired bump shape.

Of course, while the use of first external connectors 913 is one embodiment which may be used in order to provide connections for the first optical package 900, this is intended to be illustrative and is not intended to limit the embodiments. Rather, any suitable method of physically, electrically, and in some cases optically connecting the first optical package 900, such as dielectric-to-dielectric and metal-to-metal bonding, may also be utilized. Any suitable method of bonding the first optical package 900 may be used.

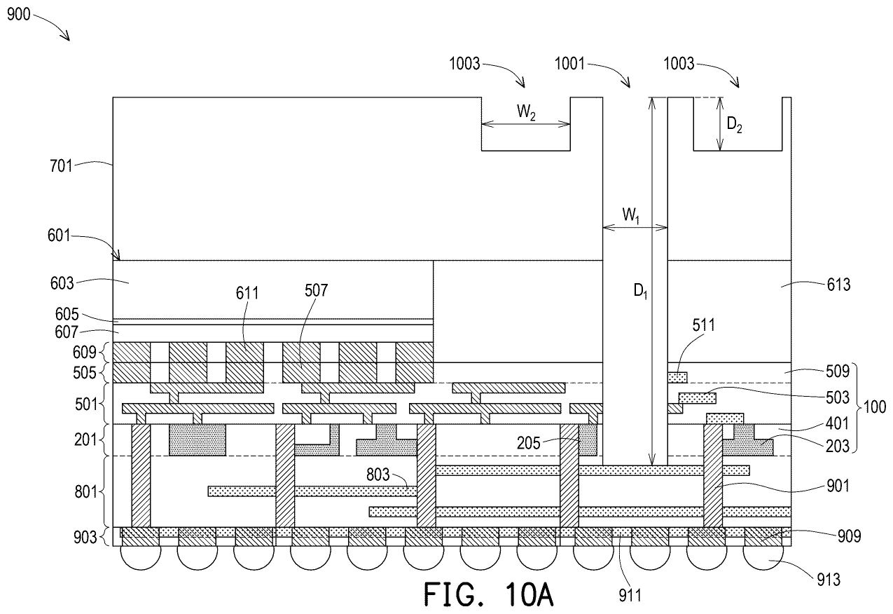

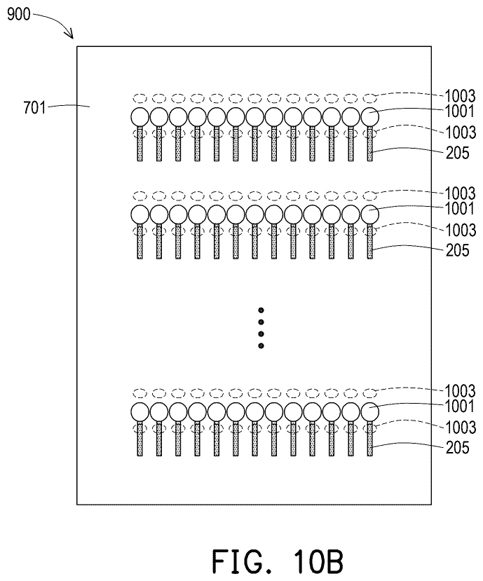

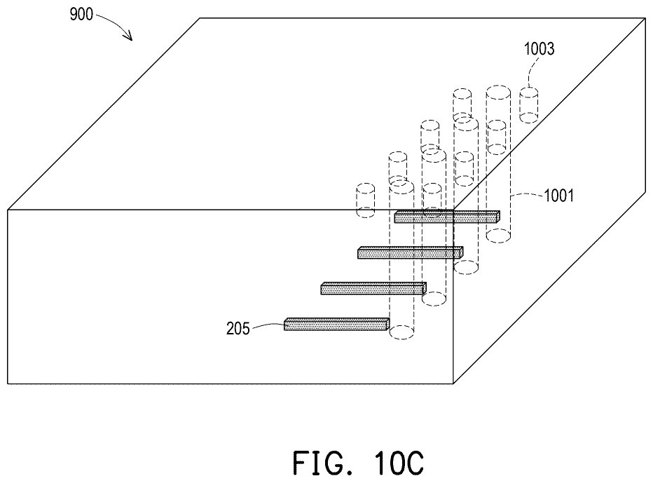

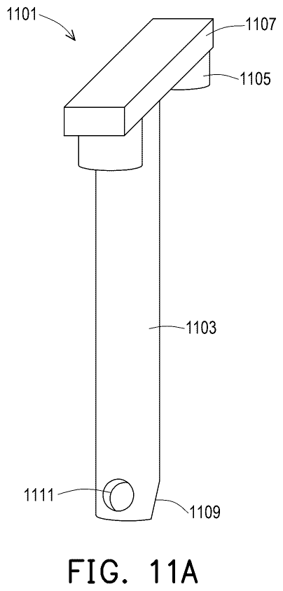

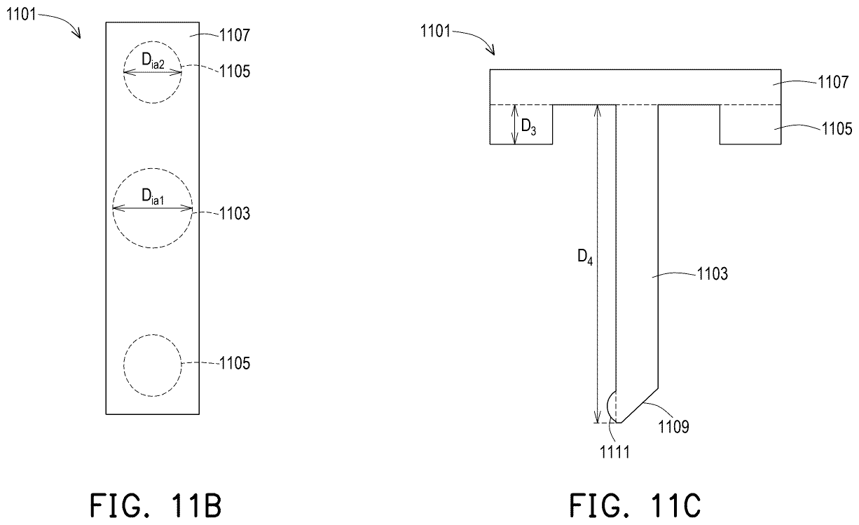

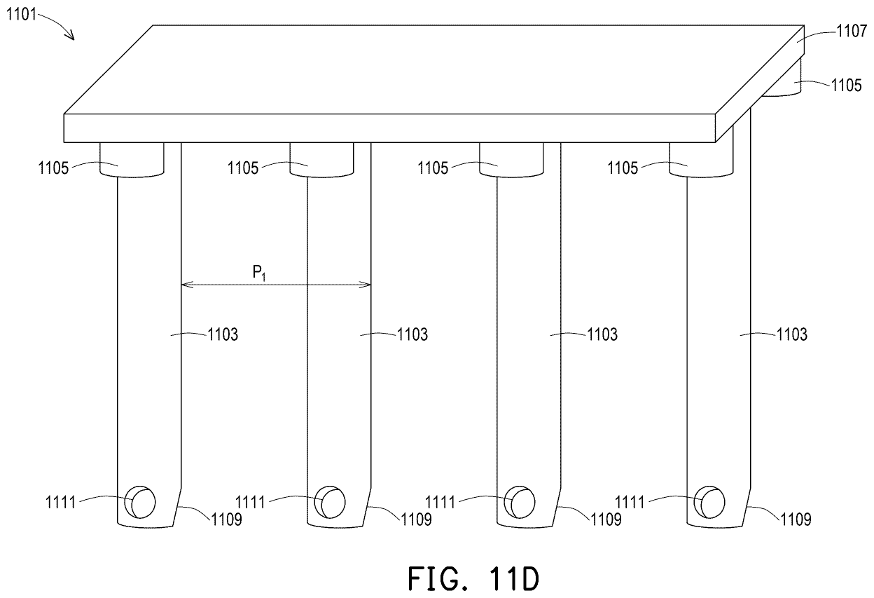

FIG. 10A illustrates formation of a receptacle opening 1001 along with one or more positioning openings 1003. In an embodiment the receptacle opening 1001 may be formed in order to allow a receptacle 1101 (not illustrated in FIG. 10A but illustrated and discussed further below with respect to FIG. 11A) to penetrate the support substrate 701, the first gap-fill material 613, and the optical interposer 100 in order to provide access to the edge coupler 205 located within the first optical components 203, the second optical components 503, and/or the third optical components 511. The receptacle opening 1001 may be formed using one or more photolithographic masking and etching process, although any suitable method of formation may be utilized.

In an embodiment the receptacle opening 1001 may be formed as a circular opening (when looking from a top down view not visible in FIG. 10A) to have a first width W₁ and a first depth D₁ sufficient to receive the receptacle 1101. For example, the receptacle opening 1001 may be formed to have the first width W₁ be between about 50 μm and about 100 μm, and a first depth D₁ to be between about 700 μm and about 800 μm. However, any suitable dimensions may be utilized.

Additionally, the receptacle opening 1001 may be formed in order to access the edge coupler 205. As such, the receptacle opening 1001 may be formed to extend into the first optical package 900 a distance further the edge coupler 205. In some embodiments the receptacle opening 1001 may be formed to extend further than the edge coupler 205 by a distance that is between about 2 and about 2.5 times the diameter of the waveguide (e.g., 5 μm to 6 μm) associated with the edge coupler 205. However, any suitable distance may be utilized.

The positioning openings 1003 are formed adjacent to the receptacle opening 1001 and are utilized to help position and align and hold the receptacle 1101 when the receptacle 1101 is placed. The positioning openings 1003 may be formed using one or more photolithographic masking and etching process, although any suitable method of formation may be utilized.

In an embodiment the positioning openings 1003 may be formed to have a second width W₂ and a second depth D₂ sufficient to position and align the receptacle 1101. For example, the positioning openings 1003 may be formed to have the second width W₂ be between about 50 μm and about 100 μm, and a second depth D₂ to be between about 50 μm and about 100 μm. However, any suitable dimensions may be utilized.

FIG. 10B illustrates a top down view of a plurality of the receptacle openings 1001 and their associated positioning openings 1003. As can be seen, the plurality of the receptacle openings 1001 may be aligned in a straight line with other, and each of the plurality of the receptacle openings 1001 are aligned with an edge coupler 205 that feeds into a waveguide of the first optical package 900.

Additionally illustrated in FIG. 10B are additional sets of the plurality of the receptacle openings 1001 that can be used to access edge couplers 205 at any position within the first optical package 900. The additional sets allows for a higher bandwidth of the optical signals 1303 to be transmitted and received from the first optical package 900. Any suitable number of receptacle openings 1001 and their associated positioning openings 1003 may be utilized and all suitable numbers are fully intended to be included within the scope of the embodiments.

FIG. 10C illustrates a simplified, isometric view of the first optical package 900 that illustrates four of the receptacle openings 1001 and their associated positioning openings 1003 (with other structures and receptacle openings 1001 being removed for clarity). As can be seen in this embodiment, the receptacle openings 1001 are formed in order to provide access to the edge couplers 205 that feed into a waveguide located within the first optical package 900.

FIG. 11A illustrates an isometric view of a portion of the receptacle 1101 that will be inserted into the receptacle openings 1001 and the positioning openings 1003 of the first optical package 900. In an embodiment the receptacle 1101 comprises a light transmission column 1103, positioning structures 1105, and a connecting piece 1107. Looking first at the light transmission column 1103, the light transmission column comprises a core material such as fused glass, silicon, sapphire, calcium fluoride (CaF₂), N-BK7, N-SF5, N-SF11, combinations of these, or the like, which is shaped to transmit the optical signals 1303, such as by being in a cylindrical shape, a polygonal shape, or the like. However, any suitable material or shape may be utilized.

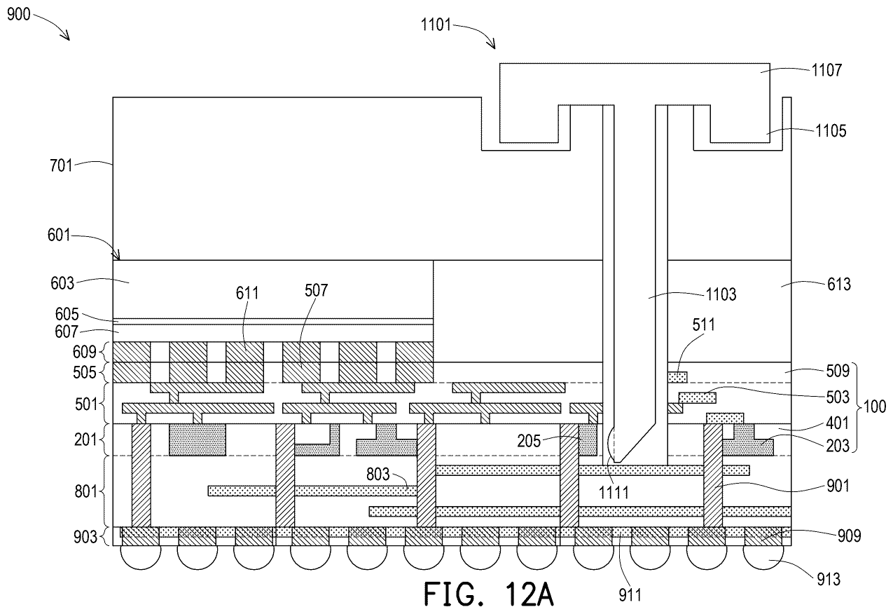

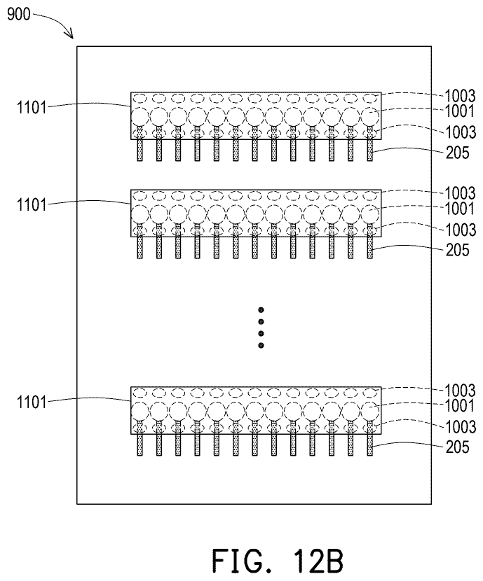

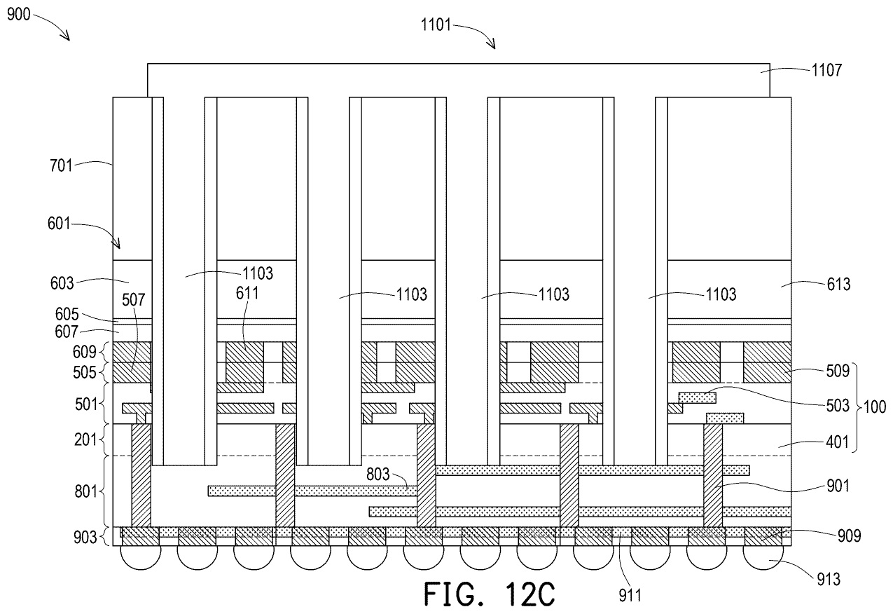

At the end of the light transmission column 1103 that will be placed adjacent to the edge coupler 205 (see FIG. 12A), there is a reflective wedge 1109 or mirror that is used to direct the optical signals 1303 into and out of the edge coupler 205 of the first optical components 203. In an embodiment the reflective wedge 1109 may be a single layer of a mirror coating or else may be a multiple layer structure such as a Bragg's reflector comprising alternating layers of silicon dioxide and amorphous silicon. Any suitable materials and any suitable shapes may be utilized to redirect the optical signals 1303.

Additionally, a lens 1111 may be positioned and aligned with the reflective wedge 1109 in order to assist in the collimation and transmission of the optical signals 1303 between the light transmission column 1103 and the edge coupler 205 of the first optical components 203. In an embodiment the lenses 1111 may be formed by shaping the material of the light transmission column 1103 using masking and etching processes, or else may be a separate structure that is independently formed and then attached to the light transmission column 1103. However, any suitable materials and processes may be utilized.

The positioning structures 1105 are utilized in order to provide an initial alignment as the receptacle 1101 is placed into the first optical package 900. In an embodiment the positioning structures 1105 have a shape that is complementary to the positioning openings 1003 located within the support substrate 701. For example, when the positioning openings 1003 are circular, the positioning structures 1105 may also be circular. However, any suitable shape may be utilized.

Finally, the receptacle 1101 may comprise the connecting piece 1107. In an embodiment the connecting piece 1107 is utilized to connect and hold the positioning structures 1105 and the light transmission column 1103 in position relative to each other. In some embodiments the connecting piece 1107 may be rectangular in shape, although any suitable shape may be utilized.

In some embodiments the various portions of the receptacle 1101 may be a single material that is formed as a single piece. In other embodiments the various portions or some combination of portions may be manufactured separately from each other and then connected together. Any suitable combination of pieces may be used, and all such combinations are fully intended to be included within the scope of the embodiments.

FIG. 11B illustrates a top view of the receptacle 1101. In this figure the connecting piece 1107 is rectangular. Further, the light transmission column 1103 is illustrated with the two positioning structures 1105 on opposing sides of the light transmission column 1103 with dashed lines. However, any suitable arrangements may be utilized.

As can be seen in FIG. 11B, the light transmission column 1103 and the two positioning structures 1105 may be shaped as circles or ovals. The light transmission column 1103 may be formed to have a first diameter Dᵢₐ₁, wherein the first width W₁ is greater than or equal to at least 1.2 times the first diameter Dᵢₐ₁. In particular embodiments the first diameter Dᵢₐ₁ is between about 40 μm and about 100 μm, such as about 90 μm. However, any suitable dimensions may be utilized.

Additionally, the two positioning structures 1105 may be formed to have a second diameter Dᵢₐ₂, wherein the second width W₂ is greater than or equal to at least 1.2 times the second diameters Dᵢₐ₂. In particular embodiments the second diameter Dᵢₐ₂ is between about 40 μm and about 90 μm. However, any suitable dimensions may be utilized.

FIG. 11C illustrates a cross-sectional view of the receptacle 1101. In this figure it can be more clearly seen how the connecting piece 1107 connects both the light transmission column 1103 (with the reflective wedge 1109 and the lens 1111) and the positioning structures 1105. In this embodiment the positioning structures 1105 may have a third depth D₃ of between about 40 μm and about 90 μm, while the light transmission column 1103 may have a fourth depth D₄ of between about 650 μm and about 750 μm. However, any suitable dimensions may be utilized.

FIG. 11D illustrates an expanded view of the receptacle 1101 wherein the receptacle 1101 comprises multiple ones of the light transmission columns 1103. As can be seen, the connecting piece 1107 connects more than one of the light transmission columns 1103, and each of the light transmission columns 1103 has a similar structure. However, in other embodiments each of the light transmission columns 1103 may have a different structure, such as having different lens 1111 in order to handle any desired wavelength of the optical signals 1303. Any suitable combination may be utilized.

Additionally, the multiple ones of the light transmission columns 1103 may be evenly spaced from each other, although in other embodiments the light transmission columns 1103 may be asymmetrically spaced from each other. In embodiments in which the light transmission columns 1103 are evenly spaced, the light transmission columns 1103 may have a first pitch P₁ of between about 127 μm and about 250 μm. However, any suitable dimension may be used.

FIG. 12A illustrates a placement of the receptacle 1101 into the first optical package 900. In particular, the one or more light transmission columns 1103 may be placed in corresponding ones of the receptacle openings 1001 while the positioning structures 1105 are placed in corresponding ones of the positioning openings 1003. As such, the positioning structures 1105 are used to provide the desired alignment for the light transmission columns 1103, wherein after placement and alignment the lens 1111 is aligned with the edge coupler 205 of the first optical components 203.

Once in place and aligned, the receptacle 1101 may be adhered using, e.g., an optical glue (not separately illustrated in FIG. 12A). However, no optical glue is needed or used in the receptacle opening 1001, leaving an air gap (or other suitable filling material) between the light transmission column 1103 and a remainder of the first optical package 9o0, and no optical glue is on the optical path from the edge coupler 205 to the receptacle 1101. In some embodiments, the optical glue comprises a polymer material such as epoxy-acrylate oligomers, and may have a refractive index between about 1 and about 3. However, any suitable material or other method of attachment may be utilized.

FIG. 12B illustrates a top down view once the receptacle 1101 has been placed into the first optical package 900. As can be seen in this view, the receptacle 1101 sits directly over the positioning openings 1003 and the receptacle openings 1001, wherein individual ones of the light transmission columns 1103 extend into the receptacle openings 1001. Additionally illustrated in this view are multiples ones of the receptacles 1101 (with each receptacle 1101 comprising multiple light transmission columns 1103) being placed into respective receptacle openings 1001. However, any suitable arrangement may be utilized.

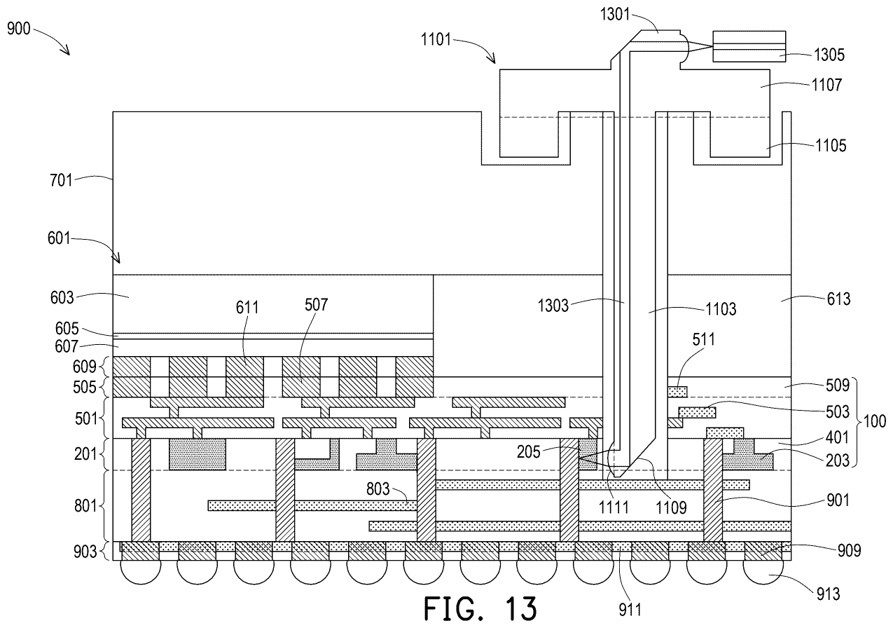

FIG. 13C illustrates a cross-sectional view of the receptacle 1101 with multiple light transmission columns 1103 extending through the first semiconductor device 601. As can be seen, the multiple light transmission columns 1103 extend through the support substrate 701, the first semiconductor device 601 and at least part of the optical interposer 100 in order to access respective edge couplers 205 (not visible in the cross-section illustrated in FIG. 12C).

FIG. 13 illustrates a placement of a fiber array unit 1301 that receives and transmits optical signals 1303 between the first optical package 900 and optical fibers 1305. In an embodiment the fiber array unit 1301 receives one or more of the optical fibers 1305, arranges the optical fibers 1305 with a fiber sheath, and directs the optical signals 1303 from the optical fibers 1305 to the receptacle 1101.

In operation the optical signals 1303 exit the fiber array unit 1301 and are directed towards the receptacle 1101. The receptacle 1101 transmits the optical signals 1303 through the light transmission column 1103 to the reflective wedge 1109, which redirects the optical signals 1303 through the lens 1111. The receptacle 1101 then directs the optical signals 1303 to the edge coupler 205 and, from the edge coupler 205, to a remainder of the first optical package 900.

By utilizing the receptacle 1101, the overall number of optical I/Os can be increased while also broadening the range of wavelengths that can be used. Additionally, by using the positioning structures 1105, an active alignment process is not needed and may be omitted, thereby reducing the fiber array unit assembly time.

By utilizing the combination of the receptacle opening 1001 and the receptacle 1101 itself the design not only increases the number of optical inputs/outputs (I/Os), but can also broaden the range of wavelengths that can be input and output from the first optical package 900, leveraging the advantages of both grating couplers (receiving off-plane optical signals) and edge couplers (higher bandwidth and less losses). Further, because there is no need for an active alignment step for placing the fiber array unit 1301, the assembly time for placing the fiber array unit 1301 can be reduced.

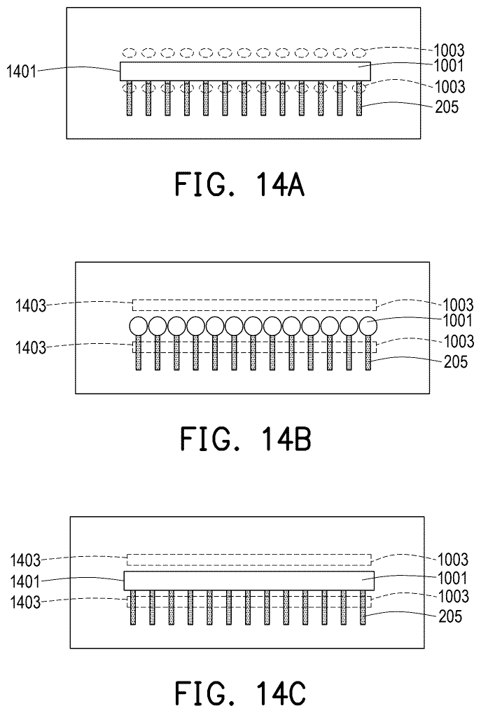

FIGS. 14A-14C illustrate other embodiments in which the receptacle opening 1001 and/or the positioning openings 1003 are formed using different shapes than the circular or oval shapes presented above. Looking first at FIG. 14A, there is illustrated a top down view of the receptacle opening 1001 and its adjacent positioning openings 1003. In this embodiment, however, instead of the receptacle openings 1001 being formed as a series of individual circular openings, the receptacle opening 1001 is formed as a single trench 1401 that can accommodate all of the desired light transmission columns 1103. Further in this embodiment, the positioning openings 1003 remain as a series of circular or oval openings.

Looking next at FIG. 14B, there is illustrated another embodiment in which the receptacle opening 1001 remains as a series of circular openings (as described above with respect to FIGS. 10A-10B). In this embodiment, however, the positioning openings 1003, instead of being formed as the series of circular or oval openings, is formed as two trenches 1403 located on opposing sides of the receptacle opening 1001.

Finally, looking at FIG. 14C, there is illustrated yet another embodiment which is a combination of the embodiments illustrated in FIGS. 14A and 14B. In particular, in this embodiment the receptacle opening 1001 is the single trench 1401 and the positioning openings 1003 are the two trenches 1403 located on opposing sides of the single trench 1401.

However, while specific combinations have been presented above, the combinations presented and discussed are intended to be illustrative of the ideas presented, and are not intended to be limiting upon the embodiments. Rather, any suitable combinations of shapes (e.g., trenches, circles, ovals, etc.) may be utilized. All such combinations are fully intended to be included within the scope of the embodiments.

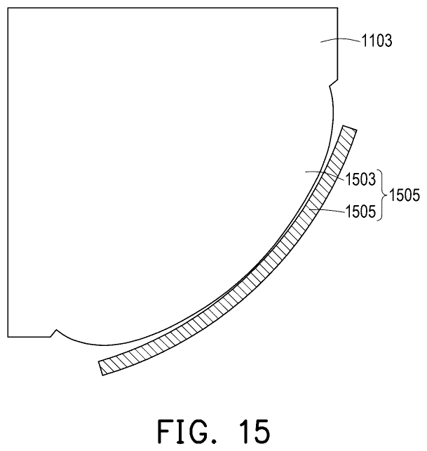

FIG. 15 illustrates another embodiment of the portion of the light transmission column 1103 which does not use the lens 1111. In this embodiment, instead of forming or placing the lens 1111, the light transmission column 1103 has a concave mirror 1501 formed from a curved portion 1503 of the material of the light transmission column 1103 and a curved mirror 1505. In an embodiment the curved portion 1503 may be formed by shaping the material of the light transmission column 1103, and the curved mirror 1505 may be formed using materials and methods similar to the reflective wedge 1109. However, any suitable materials and methods of manufacture may be utilized.

By utilizing the combination of the receptacle opening 1001 and the receptacle 1101 itself the design not only increases the number of optical inputs/outputs (I/Os), but can also broaden the range of wavelengths that can be input and output from the first optical package 900, leveraging the advantages of both grating couplers (receiving off-plane optical signals) and edge couplers (higher bandwidth and less losses). Further, because there is no need for an active alignment step for placing the fiber array unit 1301, the assembly time for placing the fiber array unit 1301 can be reduced.

In an embodiment, a method of manufacturing an optical device, the method including: receiving a first optical package, the first optical package comprising a first positioning opening and a receptacle opening; and inserting a receptacle into the receptacle opening and the first positioning opening. In an embodiment the inserting the receptacle inserts a light transmission column into the receptacle opening. In an embodiment the inserting the receptacle inserts a positioning structure into the first positioning opening. In an embodiment the receptacle comprises a reflective wedge. In an embodiment the receptacle comprises a lens aligned with the reflective wedge. In an embodiment the receptacle comprises multiple light transmission columns. In an embodiment the method further includes attaching a fiber array unit to the receptacle.

In another embodiment, a method of manufacturing an optical device includes: placing a photolithographic mask over a first optical package, the first optical package including: a photonic circuit comprising waveguides and at least one edge coupler; and an electronic circuit bonded to the photonic circuit, the electronic circuit comprising active devices and metallization layers; and etching through the photolithographic mask to form a receptacle opening into the first optical package. In an embodiment the method further includes placing a first receptacle into the receptacle opening, wherein after the placing the first receptacle a lens of the first receptacle is aligned with the edge coupler of the first optical package. In an embodiment the placing the first receptacle places a positioning structure of the first receptacle into a positioning opening of the first optical package. In an embodiment the placing the first receptacle places a plurality of light transmission columns into a single trench. In an embodiment the placing the first receptacle places a plurality of light transmission columns into a plurality of receptacle openings. In an embodiment the first receptacle comprises a connecting piece connecting a first light transmission column to a first positioning structure. In an embodiment the connecting piece connects to a second light transmission column.

In yet another embodiment an optical device includes: a first optical package; and a first receptacle extending into the first optical package through a receptacle opening and a positioning opening separate from the receptacle opening, wherein a lens of the first receptacle is aligned with an edge coupler of the first optical package. In an embodiment the first receptacle comprises a light transmission column, the lens being adjacent to the light transmission column. In an embodiment the first receptacle comprises a reflective wedge aligned with the lens. In an embodiment the first receptacle comprises positioning structures, the positioning structures within positioning openings of the first optical package. In an embodiment the first receptacle comprises a connecting piece connecting the positioning structures and the light transmission column. In an embodiment the optical device further includes a second receptacle extending into the first optical package, the second receptacle being different from the first receptacle.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing an optical device, the method comprising:
receiving a first optical package, the first optical package comprising a first positioning opening and a receptacle opening; and
inserting a receptacle into the receptacle opening and the first positioning opening.

2. The method of claim 1, wherein the inserting the receptacle inserts a light transmission column into the receptacle opening.

3. The method of claim 1, wherein the inserting the receptacle inserts a positioning structure into the first positioning opening.

4. The method of claim 1, wherein the receptacle comprises a reflective wedge.

5. The method of claim 4, wherein the receptacle comprises a lens aligned with the reflective wedge.

6. The method of claim 1, wherein the receptacle comprises multiple light transmission columns.

7. The method of claim 1, further comprising attaching a fiber array unit to the receptacle.

8. A method of manufacturing an optical device, the method comprising:
placing a photolithographic mask over a first optical package, the first optical package comprising:
a photonic circuit comprising waveguides and at least one edge coupler; and
an electronic circuit bonded to the photonic circuit, the electronic circuit comprising active devices and metallization layers; and
etching through the photolithographic mask to form a receptacle opening into the first optical package.

9. The method of claim 8, further comprising placing a first receptacle into the receptacle opening, wherein after the placing the first receptacle a lens of the first receptacle is aligned with the edge coupler of the first optical package.

10. The method of claim 9, wherein the placing the first receptacle places a positioning structure of the first receptacle into a positioning opening of the first optical package.

11. The method of claim 9, wherein the placing the first receptacle places a plurality of light transmission columns into a single trench.

12. The method of claim 9, wherein the placing the first receptacle places a plurality of light transmission columns into a plurality of receptacle openings.

13. The method of claim 9, wherein the first receptacle comprises a connecting piece connecting a first light transmission column to a first positioning structure.

14. The method of claim 13, wherein the connecting piece connects to a second light transmission column.

15. An optical device comprising:
a first optical package comprising:
a photonic circuit comprising waveguides and at least one coupler; and
an electronic circuit bonded to the photonic circuit, the electronic circuit comprising active devices and metallization layers; and
a first receptacle extending into the first optical package through a receptacle opening and a positioning opening separate from the receptacle opening, wherein a lens of the first receptacle is aligned with an edge coupler of the first optical package.

16. The optical device of claim 15, wherein the first receptacle comprises a light transmission column, the lens being adjacent to the light transmission column.

17. The optical device of claim 16, wherein the first receptacle comprises a reflective wedge aligned with the lens.

18. The optical device of claim 17, wherein the first receptacle comprises positioning structures, the positioning structures within positioning openings of the first optical package.

19. The optical device of claim 18, wherein the first receptacle comprises a connecting piece connecting the positioning structures and the light transmission column.

20. The optical device of claim 15, further comprising a second receptacle extending into the first optical package, the second receptacle being different from the first receptacle.
